(19) United States
(12) Patent Application Publication
(10) Pub. No.: US 2013/0306138 A1
(43) Pub. Date: Nov. 21, 2013

(54) WINDOW WITH AT LEAST ONE PRISM UNIT COMPRISING TWO PRISMS AND A PHOTO VOLTAIC CELL

(71) Applicants: Barak Freedman, Binyamina (IL); Ido Sovran, Tel Aviv (IL); Itay Baruchi, Tel Aviv (IL)

(72) Inventors: Barak Freedman, Binyamina (IL); Ido Sovran, Tel Aviv (IL); Itay Baruchi, Tel Aviv (IL)

(73) Assignee: PYTHAGORAS SOLAR INC., Wilmington, DE (US)

(21) Appl. No.: 13/981,782

(22) PCT Filed: Jan. 25, 2012
(86) PCT No.: PCT/IL2012/050024

§ 371 Date: Jul. 25, 2013

Related U.S. Application Data
(60) Provisional application No. 61/435,819, filed on Jan. 25, 2011.

(51) Int. Cl. H01L 31/052; G02B 19/00

(52) U.S. Cl. CPC H01L 31/0528; G02B 19/0014
USPC 136/246; 359/837; 438/65

(57) ABSTRACT

A window is provided comprising a front pane and one or more prism units each comprising: a primary prism disposed adjacent the front pane and having a primary entrance face and a primary exit face. The primary entrance face is configured to receive a first and a second portion of light that passes through the front pane. The window further comprises a secondary prism disposed adjacent the primary prism and having a secondary entrance face and a secondary exit face. The secondary entrance face is configured to receive from the primary exit face at least the second portion of light. At least one of the entrance and exit faces comprises a light diverging surface which causes divergence of light passing therethrough, and at least one of the entrance and exit faces different from the light diverging face, comprises a light converging surface configured to reduce the divergence.

### FIELD OF THE INVENTION

This invention relates to solar windows configured to generate electricity, especially those using prismatic optics to concentrate impinging solar radiation.

### BACKGROUND OF THE INVENTION

It is well known that solar radiation can be utilized by various methods to produce useable energy. One method involves the use of a photovoltaic cell, which is configured to convert solar radiation to electricity. Solar radiation collectors are typically used to gather sunlight or other radiation and direct it toward a photovoltaic cell. Often, concentrators are provided in order to focus the radiation from an area to a photovoltaic cell which is smaller than the area.

Often, a plurality of photovoltaic cells is provided to form a single module. This module may be formed so as to have characteristics separate from energy production which make it useful as a construction element. For example, the module may allow some light to pass therethrough without being used for energy production. Such a module may be installed in a building and used as a window or skylight.

Typically separation of light rays where a first portion thereof is for energy production and a second portion thereof is used for introducing light into the building is carried out by a window, such as double glazed window having a pair of prisms mounted therein. Such as window is disclosed for example in WO 2010/076796 disclosing a photo-voltaic windows and skylights integrating an array of PV cells within a double glaze cavity, and applying optical elements that direct some or most of the direct light towards the PV cell for electricity production, while allowing diffuse light to penetrate through the window into the building providing natural day light illumination and/or clear view to the outside of the building.

In WO 2010/076796 a prism pair is disclosed for concentrating direct solar radiation onto the PV cells, while allowing diffused light from the surroundings to enter through the solar window, allowing a clear view outside. Manufacturing such optical elements using plastic injection molding techniques is difficult and can get very expensive, since it is challenging to mold high quality flat surfaces in asymmetric parts such as the prism.

FIGS. 1A and 1B illustrates a pair of prior art prisms having a primary prism 12 and secondary prism 10. Due to the standard manufacturing process of the prisms 10 and 12 utilizing injection techniques, the prisms 10 and 12 are formed with a slight curvature, indicated by dashed line 14. The curvature is caused by the shrinkage of the martial of the prism when cooling down during the injection process, thus causing the surface of the prisms to act like a diverging lens. As a result, as shown in FIG. 1B, the prism 12 and 14 diverge the light rays 16 transmitted therethrough, resulting in a significant image distortion, when viewing an object through the prism pair. In particular when viewing an image through an array of prism pairs, each of which diverges the light rays traveling therethough, thus the images formed by each of the prism pairs overlap one another. When the array of such prisms is disposed in a double glazed window, such as disclosed in WO 2010/076796, a person viewing through the window will see a broken image with portions thereof overlapping others.

### SUMMARY OF THE DISCLOSED SUBJECT MATTER

According to one aspect of the presently disclosed subject matter, there is provided a window comprising a front pane and one or more prism units each comprising: a primary prism disposed adjacent the front pane and having a primary entrance face and a primary exit face. The primary entrance face is configured to receive light that passes through the front pane. The prism unit further comprising a secondary prism disposed adjacent the primary prism and having a secondary entrance face and a secondary exit face. The secondary entrance face is configured to receive from the primary exit face a second portion of the light. At least one of the entrance and exit faces comprises a light diverging surface which causes divergence of light passing therethrough. At least one of the entrance and exit faces different from the light diverging surface, comprises a light converging surface configured to reduce the divergence.

The window can further comprise an adhesive material disposed between the front pane and the primary entrance face. The adhesive material has a refractive index different from that of the primary entrance face, and the primary entrance face comprises the diverging surface or the converging surface.

Each the prism units can be provided with a PV cell, and the primary exit face can be configured to direct a first portion of the light towards the PV cell. The first portion includes at least light rays reaching the primary exit face in an angel which is larger than the critical angle thereby being totally reflected toward the PV cell.

The prism units can include a plurality of prism units, each configured to form an image of a portion of an object disposed outside the front pane of the window. The prism units is at such relative disposition and having their converging surfaces of such shapes as to ensure that the images form a continuous image of the object.

According to another aspect of the presently disclosed subject matter, there is provided a PV assembly for a double glazed window having a front pane and a rear pane with space therebetween. The assembly comprising at least one PV cell disposed in the space, the PV cell is configured to convert light rays to electrical energy, and one or more prism units. Each of the prism units comprising a primary prism disposed adjacent the front pane and having a primary entrance face and a primary exit face. The primary entrance face is configured to receive light that passes through the front pane, and to direct a first portion of the light towards the PV cell. The prism unit further comprising a secondary prism disposed adjacent the primary prism and having a secondary entrance face and a secondary exit face. The secondary entrance face is configured to receive from the primary exit face a second portion of the light different from the first portion, and the secondary exit face is configured to direct at least the second portion of light toward the rear pane. At least one of the entrance and exit faces comprises a light diverging surface which causes divergence of light passing therethrough, At least one of the entrance and exit faces different from the light diverging surface, comprises a light converging surface configured to reduce the divergence.

The PV cell can include a plurality of PV cell and the prism units can include a plurality of prism units, each configured to form an image of a portion of an object disposed outside the front pane of the window. The prism units can be at such relative disposition and having their converging surfaces of such shapes as to ensure that the images form a continuous image of the object, each one of the prism unit is associated with one of the PV cells.

The diverging surface can be configured to diverge the light in a manner pre-determined prior to the production of the corresponding prism.

The light diverging surface can be a concaved curvature formed in a controlled manner with a predetermined focal length.

The divergence can be determined after the corresponding prism is produced. The light diverging surface is a concaved curvature formed in an uncontrolled manner during the injection process of the primary and secondary prisms.

The light converging surface is a convex surface formed in a controlled manner with a predetermined focal length.

According to another aspect of the presently disclosed subject matter, there is provided a method for forming a PV assembly for a double glazed window having a front pane and a rear pane with space therebetween. The method comprising the step of providing a PV cell for mounting inside the space, the PV cell is configured to convert light rays to electrical energy. The method further comprising forming a primary prism having a primary entrance face and a primary exit face, the primary entrance face being configured to receive light that passes through the front pane, and when deposed in the space to direct a first portion of said light towards said PV cell. The method further comprising the step of forming a secondary prism having a secondary entrance face and a secondary exit face. The secondary entrance face is configured when deposed in the space to receive from the primary exit face a second portion of said light different from the first portion, and the secondary exit face being configured to direct at least the second portion of light toward the rear pane. Determining the light divergence of light passing through the primary prism and secondary prism, and providing at least one of the entrance and exit faces with a light converging surface which is configured to reduce said divergence.

At least one of the entrance and exit faces can be provided with a light diverging surface different from the light converging surface. Determining the light divergence can be carried out in consideration with the refractive index of the adhesive material disposed between the front pane and the primary entrance face.

### BRIEF DESCRIPTION OF THE DRAWINGS

In order to understand the presently disclosed subject matter and to see how it may be carried out in practice, embodiments will now be described, by way of non-limiting example only, with reference to the accompanying drawings, in which:

FIG. 1A is a side view illustration of a prior art prism unit for coupling to a window pane;

FIG. 1B is a schematic illustration of light rays traveling through the prism unit of FIG. 1;

FIG. 2 is a side view illustration prism unit according to an example of the presently disclosed subject matter;

FIG. 3 is a side view illustration of prism unit according to another example of the presently disclosed subject matter;

FIG. 4 is a side view illustration of prism unit according to a further example of the presently disclosed subject matter;

FIG. 5 is a side cross sectional view of a double glazed window having the prism unit of FIG. 2 mounted therein;

FIG. 6 is a side cross sectional view of a double glazed window having the prism unit of FIG. 3 mounted therein; and,

FIG. 7 is a side view of the double glazed window of FIG. 5.

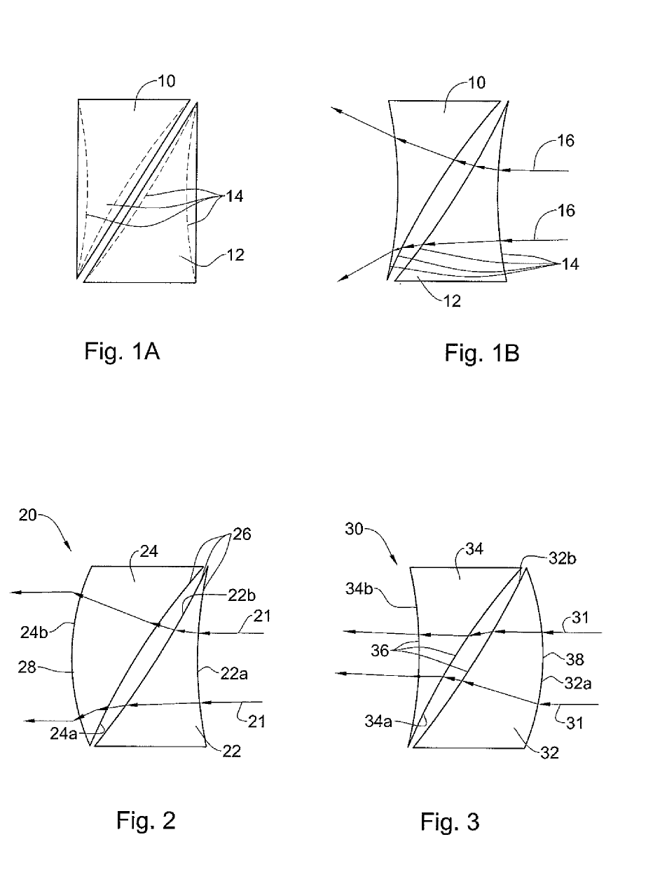

### DETAILED DESCRIPTION OF EMBODIMENTS

FIG. 2 is prism unit, here illustrated as a prism pair 20 having a primary prism 22 and a secondary prism 24, each having an entrance face 22a and 24a and an exit face 22b and 24b, respectively. The faces of the prisms 22 and 24 include one or more concaved curvatures 26 which may be naturally formed as a result of the manufacturing process of the prisms. In addition, one of the faces of the prisms 22 or 24 includes a converging surface here illustrated as a convex surface 28 configured to reduce the diverging effect of the concaved curvatures 26 by aligning the light rays traveling through the prism pair, so as to correct the image created at the exit face 24b of the second prism 24.

It is well known to those skilled in the art that obtaining accurate curved surfaces such as the, lens, or the convex surface 28 in an injection process is simpler than obtaining flat surfaces, mainly due to the ability to reach the correct curvature buy doing iterative machining of the mold. Thus, unlike the concaved curvatures 26, which are naturally formed in an uncontrolled manner, when forming a flat surface, the convex surface 28 is formed as a surface having a curvature in a controlled process, and thus can be configured as required so as to mitigate the effect of the light diverging surface of the concaved curvatures 26,

According to the illustrated example, the light diverging surface of the concaved curvatures 26 is formed on the entrance and exit faces 22a and 22b of the primary prism 22, as well as on the entrance face 24a of the secondary prism 24. The convex surface 28 on the other hand is formed on the exit face 24b of the secondary prism 24. In this example, the light rays 21 traveling through the entrance and exit faces 22a and 22b of the primary prism 22, and further through the entrance face 24a of the secondary prism 24, deviate from the original path thereof. Accordingly, the convex surface 28 on the exit face 24b of the second prism 24 is configured to direct the light rays traveling therethrogh substantially in parallel to the optical axis of the prism pair 20, thereby correcting or at least reducing the light divergence caused by the other faces.

It is appreciated that in order to allow a clear image at the exit face 24b of the secondary prism 24 the convex surface 28 does not have to be configured to direct the light rays exiting the prism pair 20 precisely in parallel to the optical axis, and to one another. That is to say that the focus length of the convex surface 28 need not be precisely the sum of the focus lengths of each concave curvature 26. Rather it is sufficient if the light rays are directed in such a way to reduce the light ray divergence, caused by the concaved curvatures 26 of the prism pair. In other words, the exit face 24b of the second prism 24 does not have to be configured in such a way that the total focal length of the prism pair 20 is set to infinity. Rather, the total focal length of the prism pair 20 can be set far enough from the prism pair so as to allow clear image when viewing therethrough.

FIG. 3 illustrates a prism unit 30 having a primary prism 32 and a second prism 34, each having an entrance face 32a and 34a and an exit face 32b and 34b, respectively. According to this example, entrance face 32a of the primary prism 32 includes a convex surface 38, while the exit face 32b thereof, as well as each one of faces 34a and 34b of the secondary prism 34 is formed with a concave curvature 36. As in the example of FIG. 2, the concaved curvatures 36 are formed during the manufacturing process when forming a prism having a flat face, while the convex surface 38 is deliberately formed with a curvature which is configured to reduce the light ray divergence caused by the concaved curvatures 36.

As shown in FIG. 3, the light rays 31, according to this example, enter the prism unit through the entrance face 32a of prism 32. The convex surface 38 causes the light rays 31 to converge, however due to the concave curvature 36 on exit face 32b as well as on entrance and exit faces 34a and 34b the light rays end up exiting the prism unit 30 substantially in parallel to the optical axis thereof. As in the previous example, the convex surface 38 on the primary entrance face 32a is configured to reduce the light ray divergence caused by the other faces.

It is appreciated that the convex surface 38 is design as a positive lens having a power which is equal to the sum of the powers of the three adjacent faces. While the three faces act as a negative lens, the face with the convex surface 38 acts as a positive lens, which substantially cancel out the power of the surfaces, and prevent ray divergence. The power of the negative lens formed on the other faces can be determined using accurate measurement techniques. Once the curvature is known the power of the lens can be calculated and then the power of the convex surface 38 can be calculated, and the mold thereof can be configured accordingly.

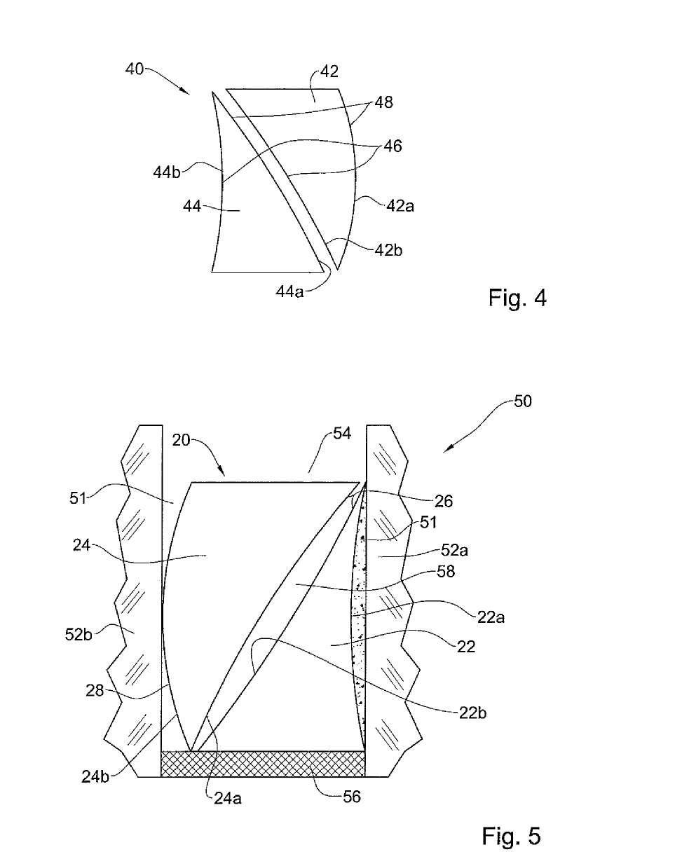

FIG. 4 illustrates a further example of the presently disclosed subject matter. According to this example, the prism unit 40 includes a primary prism 42 and a secondary prism 44, each having an entrance face 42a and 44a and an exit face 42b and 44b, respectively. According to this example, both entrance faces 42a and 44a of the primary and secondary prisms 42 and 44, respectively, include a convex surface 48. The exit faces 42b and 44b thereof, on the other hand, are each formed with a concave surface 46. According to this example both the concaved and the convex surfaces 46 and 48 are formed during the manufacturing process in a controlled manner. Thus, the concaved surface 46 are configured to substantially cancel the converging effect of the convex surfaces 48, and vice versa.

It is appreciated in accordance with the latter example, the concaved and the convex surfaces 46 and 48 can be formed on any face of the prisms 42 and 44, for example the convex surfaces 48 can be formed on the exit faces 42b and 44b, and the concave surface 46 can be formed entrance face 42a and 44a. Alternatively, one of the prisms can include concaved and the convex surfaces, while the other prism include surfaces with naturally formed concaved curvatures. Accordingly, the concaved and the convex surfaces of one prism are configured to substantially align the light rays passing through the both prisms.

It is further appreciated that the prism unit can be configured to allow light rays passing the through to be directed through the secondary exit face when substantially parallel to one another. Alternatively, the prism unit can be configured to slightly diverge light rays passing therethough, so as to magnify the image created on the exit side thereof. This can be carried out by forming at least one face of the prism unit, with a convex surface as explained above with regards to FIGS. 2 through 4, however, the convex surface can be configured to allow the light rays to diverge in a control manner.

It is appreciated that according to the example of FIG. 4 all the faces of the primary and secondary prisms are formed with convex and concaved curvatures in a controlled manner. In the examples of FIGS. 2 and 3 the convex surface is provided with a curvature the power of which is determined in accordance with the curvature naturally formed on the other faces. However, measuring the naturally formed concaved curvatures can be challenging, and can vary in different areas of each face. Thus, in accordance with the example of FIG. 4 all the entrance and exit faces of the prism unit are provided with concaved or convex curvatures which are preset, and substantially constant along the width of each face. Measurement of naturally occurring curvatures is thus not needed.

FIG. 5 shows a window 50 having a front pane 52a and a rear pane 52b defining a space 54 therebetween. A prism unit is disposed inside space 54 such as the prism pair 20 of FIG. 2 having a primary prism 22 and a secondary prism 24. According to this example entrance face 22a is configured to allow at least the majority of the light rays passing through the front pane 52a to travel through the primary prism 22. The exit face 22b is configured to direct at least a first portion of the light rays traveling through the primary prism toward a PV cell 56. Directing the first portion of the light ray can be carried out by a total internal reflection of thereof on at the exit face 22b. Total internal reflection occurs for example, when the primary and secondary prisms 22 and 24 define an air gap 58 therebetween, thus causing at least some of the light ray to be reflected when reaching the boundary between the primary prism 22 which is made of a material having a refractive index which is larger than that of the air in the air gap 58. This arrangement is known and described for example in WO 2011/048595, and accordingly the first portion of the light rays which impinge on the exit face 22b in an angle which is larger than the critical angle, is reflected back into the primary prism, and to the PV cell 56.

However, a second portion of the light ray which impinge on the exit face 22b in an angle which is smaller than the critical angle travels through the air gap 58 toward the rear pane 52b through the secondary prism 24. The second portion of the light rays may be slightly distorted due to the difference in the refractive indices between the primary prism 22 and the air gap 58. Thus the secondary prism 24 is provided and is configured to bring the second portion of the light rays back substantially to their original path.

As explained in hereinabove with regards to FIG. 2 entrance and exit faces 22a and 22b of the first prism 22, as well as on the entrance face 24a of the second prism 24 includes naturally formed concaved curvatures 26, which causes the light traveling theretrhough to diverge. Thus, the exit face 24b is provided with a convex surface 28 configured to reduce the divergence caused by the other faces. This arrangement allows a clear view when viewing through the window 50 from the rear pane 52b.

It is appreciated however, that the primary prism 22 can be coupled to the front pane 52a in such a way that there is substantially no air between the front pane and the primary entrance face 22a so as to preclude reflections on the interface therebetween. This can be carried out for example by gluing the primary prism 22 to the front pane 52a using optical adhesive material 51 which has refractive index other than that of air (r>1), such that can be as close as possible to that of the window and of the prism.

Accordingly, when calculating the necessary curvature of the convex surface 28, the difference in the refractive indices in each boundary must be taken into consideration, so as to calculate the exact effect of each face on the light rays passing therethrough. This can be carried out by using the lens makers' equation (thin lens approximation) may be used:

$$\frac{1}{f} = ( \frac{{n}_{1}}{{n}_{2}} - 1 ) ( \frac{1}{{R}_{1}} )$$

where f is the focal length, n₁ is the refractive index of the lens, n₂ is the refractive index of the external material (either air or the optical adhesive), and R₁ is the radiuses of the face of the curved surface. The equation can be used to calculate the focal length of the diverging surfaces or the required radios of the converging surface.

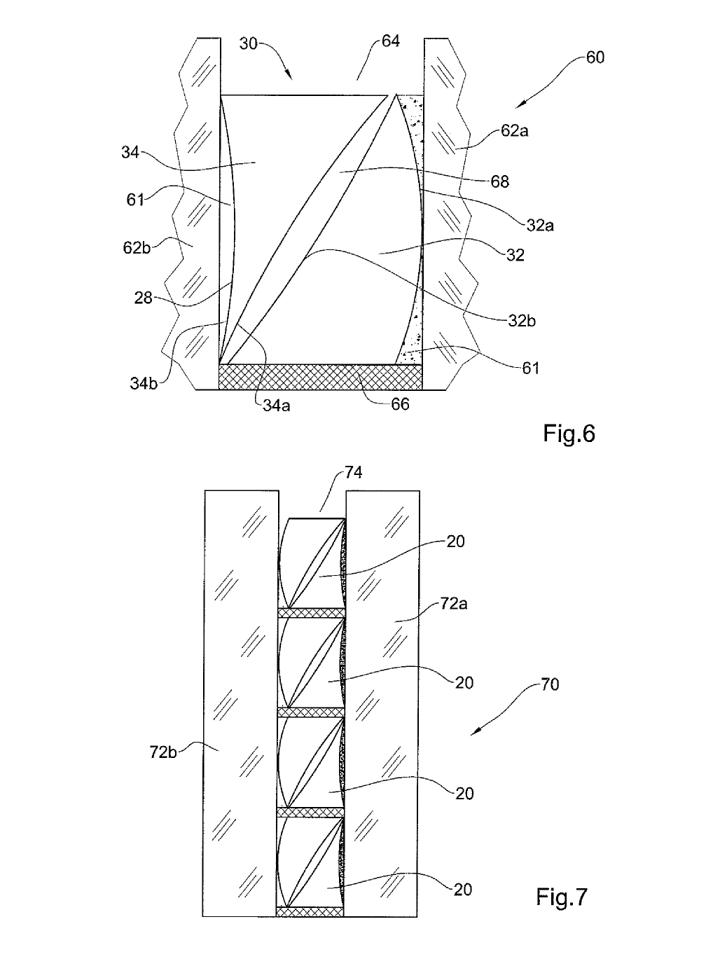

FIG. 6 shows a window 60 which is substantially the same as window 50 of FIG. 5 and having a front pane 62a and a rear pane 62b defining a space 64 therebetween. According to this example inside the space 64 there is provided a PV assembly having a PV cell 66 and the prism unit 30 of FIG. 3 having a primary prism 32 and a secondary prism 34. According to this example entrance face 32a is configured to allow at least the majority of the light rays passing through the front pane 62a to travel through the primary prism 32. In addition, the entrance face 32a is configured converge the light rays passing therethrough in so as to reduce the divergence effect of the concave curvature 36 on exit face 32b as well as on entrance and exit faces 34a and 34b which occurs when the second portion of the light, which is not directed to the PV cell 66, travels therethrough.

FIG. 7 shows a window 70 having a PV assembly disposed in a space 74 defined between a front pane 72a and a rear pane 72b. The PV assembly includes a plurality of prism units which can be for example the prism pairs 20 of FIG. 2, arranged one on top of the other and each provided with a PV cell, or array of PV cells. Each of the prism pairs 20 is configured to form an image of a portion of an object disposed outside the front pane 72a of the window 70. The prism units 20 are disposed relative to one another and having their converging surfaces of such shapes as to ensure that said images form a continuous image of the object. That is to say, the viewer can see a clear image through the window 70 without seeing overlapping portion thereof.

Those skilled in the art to which the presently disclosed subject matter pertains will readily appreciate that numerous changes, variations, and modifications can be made without departing from the scope of the invention, mutatis mutandis.

1. A window comprising a front pane and one or more prism units each comprising:
a primary prism disposed adjacent said front pane and having a primary entrance face and a primary exit face, said primary entrance face being configured to receive light that passes through the front pane; and
a secondary prism disposed adjacent said primary prism and having a secondary entrance face and a secondary exit face, said secondary entrance face being configured to receive from said primary exit face a second portion of said light;
wherein at least one of the entrance and exit faces comprises a light diverging surface which causes divergence of light passing therethrough, and wherein at least one of the entrance and exit faces different from said light diverging surface, comprises a light converging surface configured to reduce said divergence.

2. The window of claim 1 further comprising an adhesive material disposed between said front pane and said primary entrance face, and having a refractive index different from that of said primary entrance face, and wherein said primary entrance face comprises said light diverging surface or said light converging surface.

3. The window of claim 2 wherein each of said prism units is provided with a PV cell, and wherein said primary exit face is configured to direct a first portion of said light towards said PV cell, said first portion includes at least light rays reaching the primary exit face at an angle which is larger than the critical angle thereby being totally reflected toward said PV cell.

4. The window of claim 3 wherein said prism units include a plurality of prism units, each of said prism units configured to form an image of a portion of an object disposed outside the front pane of the window, said prism units being at such relative disposition and having their light converging surfaces of such shapes as to ensure that said images form a continuous image of the object.

5. The window of claim 4 wherein said light diverging surface is configured to diverge said light in a manner pre-determined prior to the production of the corresponding prism.

6. The window of claim 5 wherein said light diverging surface is a concaved curvature formed in a controlled manner with a predetermined focal length.

7. The window of claim 4 wherein said divergence is determined after the corresponding prism is produced.

8. The window according to claim 7 wherein the light diverging surface is a concaved curvature formed in an uncontrolled manner during the injection process of said primary and secondary prisms.

9. The window according to claim 7 wherein the light converging surface is a convex surface formed in a controlled manner with a predetermined focal length.

10. A PV assembly for a double glazed window having a front pane and a rear pane with space therebetween, said assembly comprising:
at least one PV cell disposed in the space, said PV cell being configured to convert light rays to electrical energy; and
one or more prism units each comprising:
a primary prism disposed adjacent the front pane and having a primary entrance face and a primary exit face, said primary entrance face being configured to receive light that passes through the front pane, and to direct a first portion of said light towards said PV cell; and
a secondary prism disposed adjacent said primary prism and having a secondary entrance face and a secondary exit face, said secondary entrance face being configured to receive from said primary exit face a second portion of said light different from the first portion, and said secondary exit face being configured to direct at least said second portion of light toward the rear pane;
wherein at least one of the entrance and exit faces comprises a light diverging surface which causes divergence of light passing therethrough, and wherein at least one of the entrance and exit faces different from said light diverging surface, comprises a light converging surface configured to reduce said divergence.

11. The PV assembly of claim 10 wherein said PV cell includes a plurality of PV cells and wherein said prism units include a plurality of prism units, each of said prism units configured to form an image of a portion of an object disposed outside the front pane of the window, said prism units being at such relative disposition and having their light converging surfaces of such shapes as to ensure that said images form a continuous image of the object, each one of said prism unit is associated with one of said PV cells.

12. The PV assembly of claim 11 wherein said light diverging surface is configured to diverge said light in a manner pre-determined prior to the production of the corresponding prism.

13. The PV assembly of claim 12 wherein said light diverging surface is a concaved curvature formed in a controlled manner with a predetermined focal length.

14. The PV assembly of claim 10 wherein said divergence is determined after the corresponding prism is produced.

15. The PV assembly according to claim 14 wherein the light diverging surface is a concaved curvature formed in an uncontrolled manner during the injection process of said primary and secondary prisms.

16. The PV assembly according to claim 14 wherein the light converging surface is a convex surface formed in a controlled manner with a predetermined focal length.

17. A method for forming a PV assembly for a double glazed window having a front pane and a rear pane with space therebetween, the method comprising:
providing a PV cell for mounting inside the space, said PV cell being configured to convert light rays to electrical energy; and
forming a primary prism having a primary entrance face and a primary exit face, said primary entrance face being configured to receive light that passes through the front pane, and when disposed in the space to direct a first portion of said light towards said PV cell;
forming a secondary prism having a secondary entrance face and a secondary exit face, said secondary entrance face being configured when disposed in the space to receive from said primary exit face a second portion of said light different from the first portion, and said secondary exit face being configured to direct at least said second portion of light toward the rear pane;
determining the light divergence of light passing through said primary prism and secondary prism; and
providing at least one of the entrance and exit faces with a light converging surface being configured to reduce said divergence.

18. The method of claim 17 wherein at least one of the entrance and exit faces is provided with a light diverging surface different from said light converging surface.

19. The method of claim 18 wherein said step of determining the light divergence is carried out by measuring the radius of the concaved surfaces formed on each of said entrance and exit faces, and wherein said light converging surface is provided with a focal length that can reduce the divergence caused by said concaved surfaces.

20. The method of claim 19 wherein said step of determining the light divergence is carried out in consideration with the refractive index of the adhesive material disposed between the front pane and the primary entrance face.
